(19) United States
(12) Patent Application Publication
(10) Pub. No.: US 2026/0362846 A1
(43) Pub. Date: Nov. 12, 2026

(54) SEMICONDUCTOR PACKAGE, ELECTRONIC DEVICE, AND METHOD FOR CONTROLLING SEMICONDUCTOR PACKAGE

(71) Applicant: SONY SEMICONDUCTOR SOLUTIONS CORPORATION, KANAGAWA (JP)

(72) Inventor: TSUYOSHI WATANABE, KANAGAWA (JP)

(21) Appl. No.: 19/129,656

(22) PCT Filed: Sep. 22, 2023
(86) PCT No.: PCT/JP2023/034401

§ 371 Date: May 13, 2025

(30) Foreign Application Priority Data
Nov. 17, 2022 (JP) 2022-183786

(51) Int. Cl. H10F 77/60; H10F 39/00; H10F 39/95; H10N 10/17; H10N 19/00

(52) U.S. Cl. CPC H10F 77/60; H10F 39/026; H10F 39/804; H10F 39/95; H10N 10/17; H10N 19/00

(57) ABSTRACT

Miniaturization is facilitated in a semiconductor package provided with a Peltier module. A semiconductor package includes a mounting substrate, a semiconductor chip, and a Peltier module. In the semiconductor package including the mounting substrate, the semiconductor chip, and the Peltier module, the semiconductor chip is arranged in an attachment region in a substrate plane of the mounting substrate. In addition, in the semiconductor package including the mounting substrate, the semiconductor chip, and the Peltier module, the Peltier module is connected to a periphery of the attachment region in the substrate plane of the mounting substrate.

### TECHNICAL FIELD

The present technology relates to a semiconductor package. In detail, the present technology relates to a semiconductor package using a Peltier element, an electronic device, and a method for controlling the semiconductor package.

### BACKGROUND ART

Conventionally, in a semiconductor chip having large power consumption, such as an image sensor, heat during operation adversely affects performance, and thus thermal management is required. For example, there has been proposed a semiconductor package in which a Peltier module using a Peltier element is connected to a lower surface of a substrate having a semiconductor chip arranged on an upper surface thereof, and a heat sink is disposed below the Peltier module (see, for example, Patent Document 1).

### CITATION LIST

### Patent Document

Patent Document 1: Japanese Patent Application Laid-Open No. 2006-222776

### SUMMARY OF THE INVENTION

### Problems to be Solved by the Invention

In the above-described conventional technology, the Peltier module and the heat sink are utilized to dissipate heat produced in the semiconductor chip. However, in the above-described semiconductor package, disposing the Peltier module makes it difficult to ensure a space for mounting a component on the lower surface of the substrate. For this reason, it is required to expand the substrate area, but the size of the semiconductor package will increase accordingly. If the Peltier module and the heat sink are reduced, miniaturization can be achieved, but heat dissipation performance is degraded, which is not preferable. In this manner, the above-described semiconductor package has a disadvantage that miniaturization is difficult.

The present technology has been designed in view of such a situation, and an object thereof is to facilitate miniaturization of a semiconductor package provided with a Peltier module.

### Solutions to Problems

The present technology has been made to solve the above-described disadvantage, and a first aspect thereof is a semiconductor package including: a mounting substrate; a semiconductor chip arranged in an attachment region in a substrate plane of the mounting substrate; and a Peltier module connected to a periphery of the attachment region in the substrate plane, and a method for controlling the semiconductor package. This brings about an effect of facilitating miniaturization.

In addition, in the first aspect, the Peltier module may include a heat dissipation-side substrate, a heat absorption-side substrate connected to the mounting substrate, and a Peltier element disposed between the heat dissipation-side substrate and the heat absorption-side substrate. This brings about an effect that the semiconductor chip is cooled.

In addition, in the first aspect, both the heat dissipation-side substrate and the heat absorption-side substrate may be flexible substrates having an opening. This brings about an effect that the height of the semiconductor package can be lowered.

In addition, in the first aspect, the heat absorption-side substrate may be a ceramic substrate having an opening. This brings about an effect that heat is absorbed via the ceramic substrate.

In addition, in the first aspect, the heat dissipation-side substrate may be a ceramic substrate having an opening. This brings about an effect that heat is dissipated via the ceramic substrate.

In addition, in the first aspect, the heat dissipation-side substrate may be a transparent substrate. This brings about an effect that glass is no longer necessary.

In addition, in the first aspect, the Peltier module may include: a metal plate having an opening; a heat dissipation-side substrate connected to the metal plate; a heat absorption-side substrate connected to the mounting substrate; and a Peltier element disposed between the heat dissipation-side substrate and the heat absorption-side substrate. This brings about an effect that heat is dissipated via the metal plate.

In addition, in the first aspect, the metal plate may be fixed to an attachment portion, and a linear expansion coefficient and a thermal conductivity of the metal plate may be larger than those of the heat dissipation-side substrate and smaller than those of the attachment portion. This brings about an effect of suppressing thermal deformation of the metal plate while ensuring thermal conductive properties of the metal plate.

In addition, in the first aspect, the Peltier module may further include a sealing resin that seals respective side surfaces of the heat dissipation-side substrate and the Peltier element. This brings about an effect that the space in the semiconductor package is hermetically isolated.

In addition, in the first aspect, the semiconductor chip may photoelectrically convert incident light to generate image data. This brings about an effect that image data is captured.

In addition, in the first aspect, glass that seals off a space formed by the Peltier module and the mounting substrate may be further included. This brings about an effect that the space in the semiconductor package is hermetically isolated.

In addition, in the first aspect, a first application region along an outer periphery of the mounting substrate, a mounting land to which the Peltier module is connected, and a second application region between the application region and the mounting land may be disposed on the substrate plane, the mounting land and the first application region may be bonded to the Peltier module with a conductive adhesive, and the second application region may be bonded to the Peltier module with a non-conductive adhesive. This brings about an effect that the first application region and the mounting land are insulated.

In addition, a second aspect of the present technology is an electronic device including: a mounting substrate; a semiconductor chip arranged in an attachment region in a substrate plane of the mounting substrate; a Peltier module connected to a periphery of the attachment region in the substrate plane; and a control unit that supplies an electric current to the Peltier module. This brings about an effect that the electronic device is miniaturized.

### BRIEF DESCRIPTION OF DRAWINGS

FIG. 1 is a block diagram representing a configuration example of an imaging device according to a first embodiment of the present technology.

FIG. 2 is a cross-sectional view representing a configuration example of a semiconductor package according to the first embodiment of the present technology.

FIG. 3 is a top view and a bottom view of the semiconductor package according to the first embodiment of the present technology.

FIG. 4 is a view for explaining a mounting example of the semiconductor package according to the first embodiment of the present technology.

FIG. 5 depicts an example of a top view, a cross-sectional view, and a bottom view of a Peltier module according to the first embodiment of the present technology.

FIG. 6 is a view for explaining an array of Peltier elements according to the first embodiment of the present technology.

FIG. 7 depicts an example of a top view and a cross-sectional view of an interposer substrate according to the first embodiment of the present technology.

FIG. 8 is a view representing a step of forming electrodes on a ceramic substrate on a heat dissipation side according to the first embodiment of the present technology.

FIG. 9 is a view representing a step of applying solder to the ceramic substrate on the heat dissipation side according to the first embodiment of the present technology.

FIG. 10 is a view representing a step of forming electrodes on a ceramic substrate on a heat absorption side according to the first embodiment of the present technology.

FIG. 11 is a view representing a step of applying solder to the ceramic substrate on the heat absorption side according to the first embodiment of the present technology.

FIG. 12 is a view representing a step of disposing the Peltier elements according to the first embodiment of the present technology.

FIG. 13 is a view representing a step of soldering the ceramic substrates according to the first embodiment of the present technology.

FIG. 14 is a view representing a step of applying a sealing resin according to the first embodiment of the present technology.

FIG. 15 depicts an example of a cross-sectional view and a top view of the Peltier module in which application of the sealing resin has been completed according to the first embodiment of the present technology.

FIG. 16 is a view representing a step of bonding a metal plate according to the first embodiment of the present technology.

FIG. 17 depicts an example of a cross-sectional view and a bottom view of an organic substrate according to the first embodiment of the present technology.

FIG. 18 is a view representing a step of mounting components on the organic substrate according to the first embodiment of the present technology.

FIG. 19 is a view representing a step of singulating the organic substrate according to the first embodiment of the present technology.

FIG. 20 is a view representing a step of die bonding according to the first embodiment of the present technology.

FIG. 21 is a view representing a step of wire bonding according to the first embodiment of the present technology.

FIG. 22 is a view representing a step of applying a non-conductive adhesive according to the first embodiment of the present technology.

FIG. 23 is a view representing a step of applying a conductive adhesive according to the first embodiment of the present technology.

FIG. 24 is a view representing a step of bonding the Peltier module according to the first embodiment of the present technology.

FIG. 25 is a view representing a step of applying an adhesive according to the first embodiment of the present technology.

FIG. 26 is a view representing a step of arranging glass according to the first embodiment of the present technology.

FIG. 27 is a flowchart representing an example of a method for controlling the semiconductor package according to the first embodiment of the present technology.

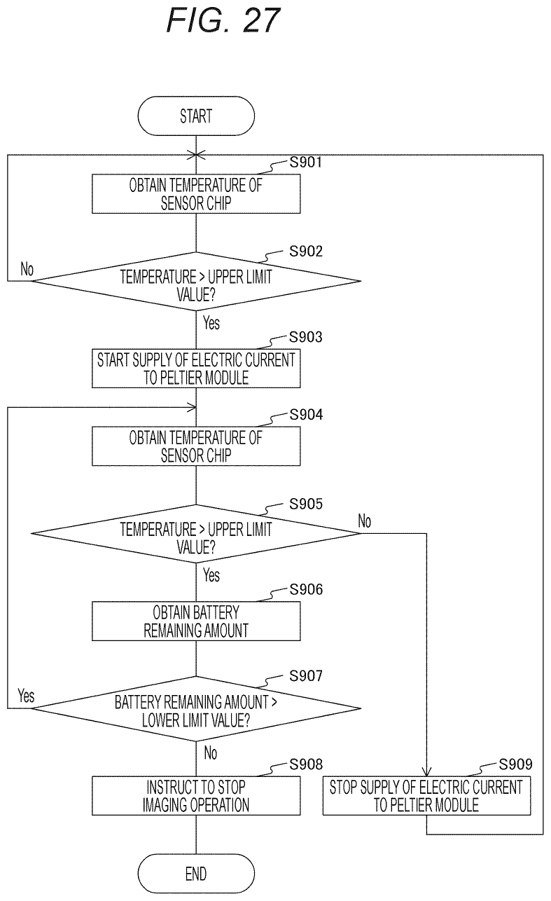

FIG. 28 depicts an example of a top view, a cross-sectional view, and a bottom view of a Peltier module according to a second embodiment of the present technology.

FIG. 29 depicts an example of a top view, a cross-sectional view, and a bottom view of a Peltier module according to a third embodiment of the present technology.

FIG. 30 is a block diagram representing a schematic configuration example of a vehicle control system.

FIG. 31 is an explanatory diagram representing an example of installation positions of an imaging section.

### MODE FOR CARRYING OUT THE INVENTION

Modes (hereinafter referred to as embodiments) for carrying out the present technology will be described below. The description will be given in the following order.

1. First Embodiment (Example in which Peltier Module is Connected to Upper Surface of Interposer Substrate)

2. Second Embodiment (Example in which Peltier Module Including Sapphire Substrate is Connected to Upper Surface of Interposer Substrate)

3. Third Embodiment (Example in which Peltier Module Including Flexible Substrate is Connected to Upper Surface of Interposer Substrate)

4. Example of Application to Mobile Object

### 1. First Embodiment

### Configuration Example of Imaging Device

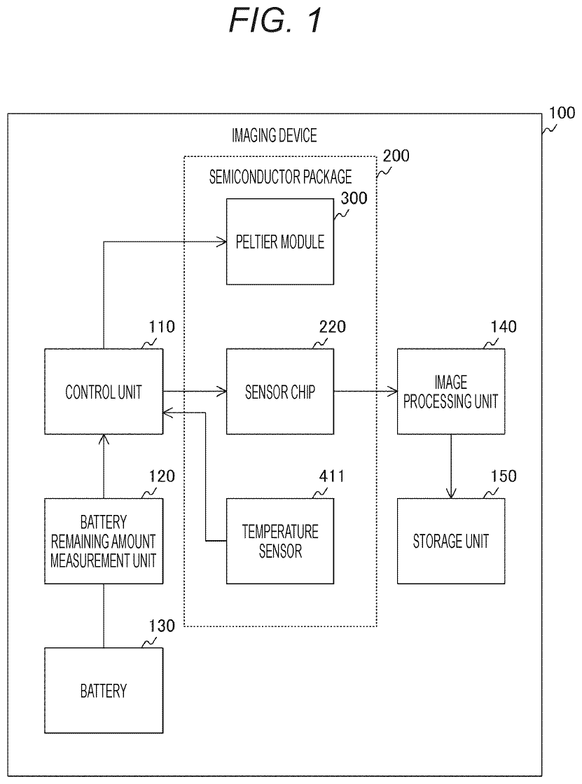

FIG. 1 is a block diagram representing a configuration example of an imaging device 100 according to a first embodiment of the present technology. The imaging device 100 is an electronic device that captures image data and includes a control unit 110, a battery remaining amount measurement unit 120, a battery 130, a semiconductor package 200, an image processing unit 140, and a storage unit 150. A mirrorless camera, a smartphone, a notebook personal computer having an imaging function, or the like is supposed as the imaging device 100. In addition, the semiconductor package 200 includes a Peltier module 300, a sensor chip 220, and a temperature sensor 411. Note that the imaging device 100 is an example of an electronic device described in the claims.

The control unit 110 controls the entire imaging device 100. The control unit 110 obtains a temperature measured by the temperature sensor 411 during imaging and determines whether or not the obtained temperature is higher than a predetermined upper limit value. In a case where the temperature is higher than the upper limit value, the control unit 110 supplies an electric current to the Peltier module 300 to drive the Peltier module 300. Then, during driving of the Peltier module 300, the control unit 110 obtains a temperature measured by the temperature sensor 411 and determines again whether or not the obtained temperature is higher than the upper limit value. In a case where the temperature is higher than the upper limit value, the control unit 110 obtains a battery remaining amount measured by the battery remaining amount measurement unit 120. In a case where the battery remaining amount is equal to or less than a predetermined lower limit value, the control unit 110 controls the Peltier module 300 and the sensor chip 220 to stop their operations.

The battery remaining amount measurement unit 120 measures the remaining amount of the battery 130. The battery remaining amount measurement unit 120 supplies the measured battery remaining amount to the control unit 110.

The battery 130 supplies electric power to circuits and elements in the imaging device 100. As the battery 130, for example, a secondary battery is used.

The Peltier module 300 releases heat produced in the sensor chip 220 by the Peltier effect.

The sensor chip 220 photoelectrically converts incident light to generate image data. A complementary metal oxide semiconductor (CMOS) image sensor (CIS) is used as the sensor chip 220, for example. The sensor chip 220 generates image data under the control of the control unit 110 and supplies the generated data to the image processing unit 140.

The temperature sensor 411 measures the temperature of the sensor chip 220. The temperature sensor 411 supplies the measured temperature to the control unit 110.

The image processing unit 140 performs various kinds of image processing such as demosaic processing on the image data. The image processing unit 140 stores the processed image data in the storage unit 150.

The storage unit 150 stores the image data.

Note that, although the image processing unit 140 and the storage unit 150 are provided outside the semiconductor package 200, some or all of them can also be provided in the sensor chip 220. For example, the sensor chip 220 may have a stacked structure in which a plurality of chips is stacked, and the image processing unit 140 and the storage unit 150 may be disposed on any of these chips.

In addition, although the temperature sensor 411 is disposed in the semiconductor package 200, this sensor can also be disposed outside the semiconductor package 200.

In addition, although the control unit 110 is disposed outside the semiconductor package 200, some or all of the functions of the control unit 110 can also be implemented by a circuit in the semiconductor package 200.

### Configuration Example of Semiconductor Package

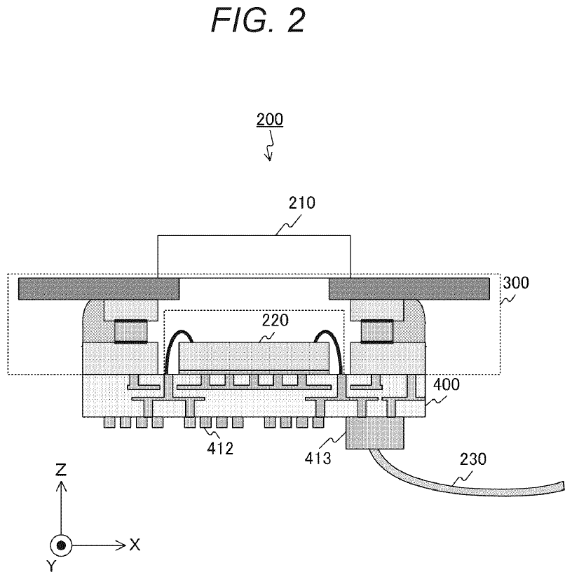

FIG. 2 is a cross-sectional view representing a configuration example of the semiconductor package 200 according to the first embodiment of the present technology. The semiconductor package 200 includes a glass 210, the Peltier module 300, the sensor chip 220, and an interposer substrate 400.

Hereinafter, a predetermined axis parallel to a substrate plane of the interposer substrate 400 will be assumed as an “X axis”, and an axis perpendicular to the substrate plane will be assumed as a “Z axis”. An axis perpendicular to the X axis and the Z axis will be assumed as a “Y axis”. The drawing is a cross-sectional view as viewed from a Y-axis direction.

In addition, hereinafter, a direction from the interposer substrate 400 to the sensor chip 220 will be assumed as an “upper” direction.

The sensor chip 220 is arranged on an attachment region of an upper surface of the interposer substrate 400 and is electrically connected by wire bonding. In addition, a predetermined number of peripheral components 412 and a connector 413 are disposed on a lower surface of the interposer substrate 400. A flexible cable 230 is connected to the connector 413.

In addition, wiring that electrically connects each of the sensor chip 220 and the Peltier module 300 to the connector 413 is formed in the interposer substrate 400. Therefore, a circuit (such as the control unit 110) outside the semiconductor package 200 is allowed to transmit and receive image data and a control signal to and from the sensor chip 220, as well as to supply an electric current to the Peltier module 300, via the flexible cable 230. In addition, the temperature sensor 411 (not represented in the drawing) is disposed in the interposer substrate 400, for example, and a temperature measured by the temperature sensor 411 is transmitted to the control unit 110 or the like via the connector 413.

Note that the sensor chip 220 is an example of a semiconductor chip described in the claims, and the interposer substrate 400 is an example of a mounting substrate described in the claims.

The Peltier module 300 is connected to a periphery of the attachment region on which the sensor chip 220 is arranged, on the upper surface of the interposer substrate 400. The Peltier module 300 surrounds side surfaces of the sensor chip 220, and a space (in other words, a cavity) is formed by the interposer substrate 400 and the Peltier module 300. An upper portion of the cavity is sealed off with the glass 210.

In a case where the sensor chip 220 has multiple pixels and operates at a high speed, power consumption increases, and heat during operation adversely affects imaging characteristics and reliability. For this reason, it is necessary to forcibly dissipate heat from the sensor chip 220, and the volume and weight of the semiconductor package 200 and the imaging device 100 tend to increase due to a cooling member and a heat dissipation member for this purpose.

Here, a semiconductor package in which the sensor chip 220 is disposed on the upper surface of the interposer substrate 400, a Peltier module is connected to the lower surface thereof, and a heat sink is disposed below the Peltier module is supposed as a comparative example. In a mirrorless camera or the like, components may sometimes need to be mounted also on a back surface of the interposer substrate 400 for lighter weight and space saving. However, in the comparative example, since the Peltier module is disposed on the lower surface of the interposer substrate 400, it is difficult to ensure a space for mounting components on the lower surface thereof. For this reason, it is required to expand the substrate area, but the size of the semiconductor package will increase accordingly. If the Peltier module and the heat sink are reduced, miniaturization can be achieved, but heat dissipation performance is degraded, which is not preferable.

In contrast to this, according to the configuration in which the sensor chip 220 and the Peltier module 300 are connected to the upper surface of the interposer substrate 400, it is easy to mount components on the lower surface of the interposer substrate 400, as depicted in the drawing. Therefore, the substrate area can be made narrower than that of the comparative example, and the semiconductor package 200 can be miniaturized. In addition, warpage of an imaging surface of the sensor chip 220 due to a temperature change at the time of controlling the temperature of the sensor chip 220 is also lessened, and image quality is not deteriorated. From such features, it is possible to miniaturize the imaging device 100 on which the sensor chip 220 that captures a moving image with a large view angle size is mounted, and the portability is improved.

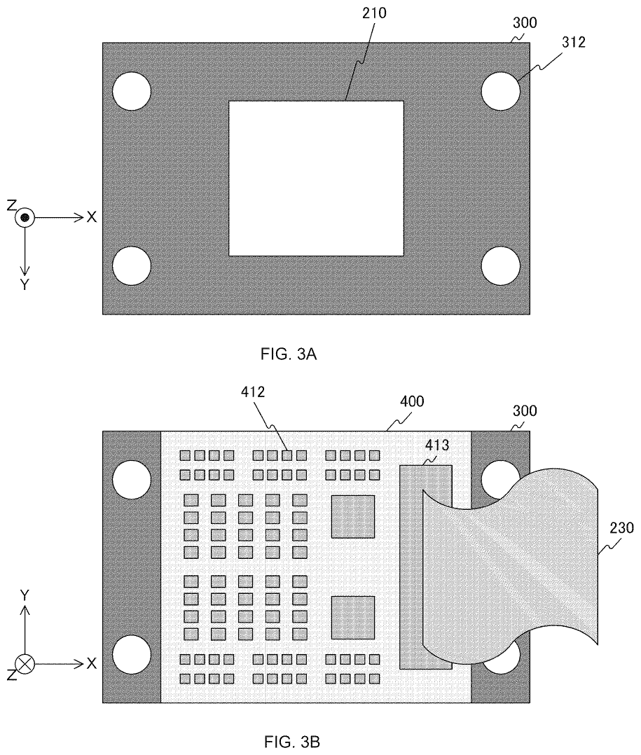

FIG. 3 is a top view and a bottom view of the semiconductor package 200 according to the first embodiment of the present technology. In the drawing, a depicts an example of a top view of the semiconductor package 200, and b of the drawing depicts an example of a bottom view of the semiconductor package 200.

As illustrated in a of the drawing, screw holes 312 are provided at each of four corners of the Peltier module 300. In addition, as illustrated in b of the drawing, various kinds of peripheral components 412 can be disposed on the lower surface of the interposer substrate 400.

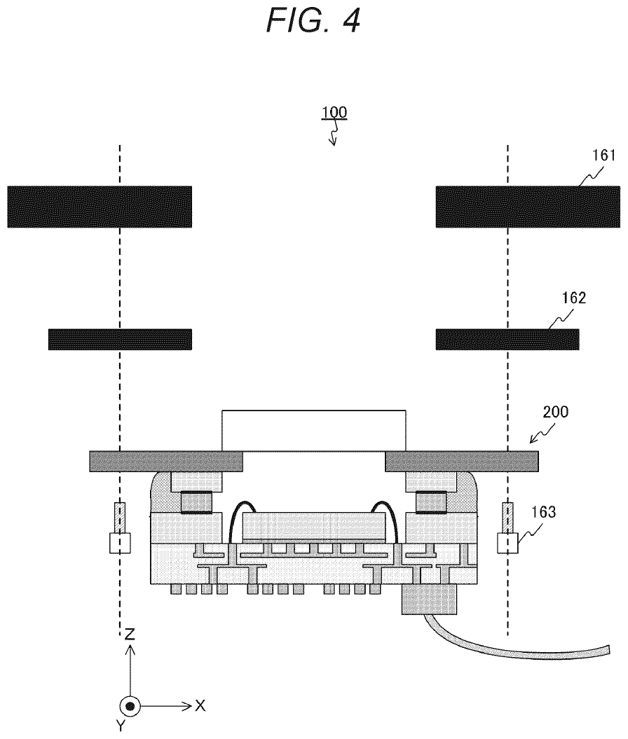

FIG. 4 is a view for explaining a mounting example of the semiconductor package 200 according to the first embodiment of the present technology. An attachment portion 161 and a heat conductive sheet 162 are provided in the imaging device 100.

The semiconductor package 200 is fixed to the attachment portion 161 with screws 163 with the heat conductive sheet 162 sandwiched therebetween.

With the configuration illustrated in FIGS. 2 to 4, when an electric current is supplied to the Peltier module 300 via the connector 413 in FIG. 3, heat is dissipated from the upper surface of the interposer substrate 400, and the sensor chip 220 is cooled via the substrate. The released heat is released to a housing of imaging device 100 from the Peltier module 300 through the heat conductive sheet 162 and the attachment portion 161 in FIG. 4.

### Configuration Example of Peltier Module

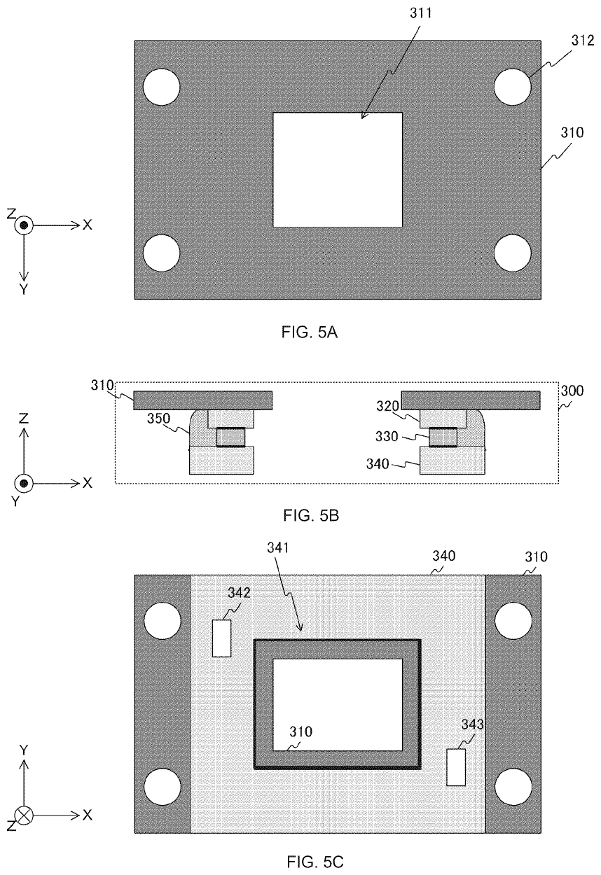

FIG. 5 depicts an example of a top view, a cross-sectional view, and a bottom view of the Peltier module 300 according to the first embodiment of the present technology. In the drawing, a depicts an example of a top view of the Peltier module 300, and b of the drawing depicts an example of a cross-sectional view of the Peltier module 300 as viewed from the Y-axis direction. In the drawing, c depicts an example of a bottom view of the Peltier module 300.

As illustrated in b of the drawing, the Peltier module 300 includes a metal plate 310, a ceramic substrate 320, Peltier elements 330, and a ceramic substrate 340.

The ceramic substrate 340 is a frame-shaped substrate made from ceramic and having an opening and is disposed on a lower side of the ceramic substrate 320 (in other words, a heat absorption side). The ceramic substrate 320 is a frame-shaped substrate made from ceramic and having an opening and is disposed on an upper side of the ceramic substrate 340 (in other words, a heat dissipation side). In addition, the area of the ceramic substrate 320 on the upper side is narrower than that of the ceramic substrate 340 on the lower side so that a sealing resin 350 can be applied. Furthermore, the thickness of the ceramic substrate 340 on the lower side is about 30% larger than that of the ceramic substrate 320 on the upper side so that the ceramic substrate 320 does not follow deformation when occurring due to a temperature rise at the time of heat dissipation.

Note that the ceramic substrate 320 is an example of a heat dissipation-side substrate described in the claims, and the ceramic substrate 340 is an example of a heat absorption-side substrate described in the claims.

The Peltier elements 330 are disposed between the ceramic substrate 320 and the ceramic substrate 340 and have a size in a Z-axis direction (that is, a height) of one millimeter (mm) or less. A plurality of semiconductors (not represented in the drawing) constituting the Peltier elements 330 is arrayed along an outer periphery of the opening of the ceramic substrate 320. In addition, the respective side surfaces of the ceramic substrate 320 and the Peltier elements 330 are sealed with a non-conductive sealing resin 350 so that foreign matters and moisture do not enter the cavity through gaps between these semiconductors. As the sealing resin 350, for example, a silicone or epoxy thermosetting resin having a viscosity of 30 pascal seconds (Pa·s) or more and high thixotropy and having little outgassing is used.

The metal plate 310 is a substrate made from metal and subjected to black plating and is bonded to be in contact with an upper surface of the ceramic substrate 320 with the sealing resin 350. As a material of the metal plate 310, a material having a linear expansion coefficient and a thermal conductivity larger than those of the ceramic substrate 320 and smaller than those of the attachment portion 161 illustrated in FIG. 4 is used. This makes it possible to suppress thermal deformation of the metal plate 310 while ensuring thermal conductive properties of the metal plate 310. In addition, thermal stress is generated due to a difference in thermal expansion coefficient between the glass 210 (not represented in the drawing) on the upper surface of metal plate 310 and the metal plate 310. Therefore, as the glass 210, glass capable of sufficiently alleviating the thermal stress (heat-resistant glass or the like) is used.

As illustrated in a of FIG. 5, the metal plate 310 has an opening 311 at a center portion and has the screw holes 312 at four corners as viewed from the Z-axis direction.

In addition, as illustrated in c of the drawing, the ceramic substrate 340 has an opening 341 at a center portion and has terminals 342 and 343 on a lower surface as viewed from the Z-axis direction. The thick line in c of the drawing indicates the outer periphery of the opening 341.

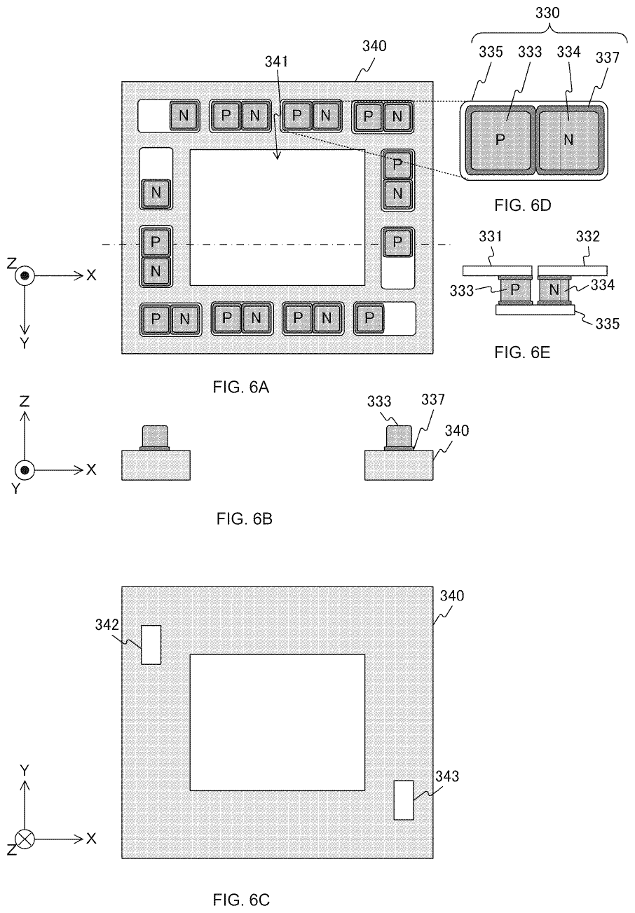

FIG. 6 is a view for explaining an array of Peltier elements 330 according to the first embodiment of the present technology. In the drawing, a depicts an example of a top view of the ceramic substrate 340 in which the Peltier elements 330 are arrayed, and b of the drawing depicts an example of a cross-sectional view of the Peltier elements 330 and the ceramic substrate 340 when taken along the dashed-dotted line in a of the drawing. In the drawing, c depicts an example of a bottom view of the ceramic substrate 340. In the drawing, d depicts an example of an enlarged view of the Peltier element 330. In the drawing, e is a cross-sectional view of a unit structure of the Peltier element 330.

As illustrated in e of the drawing, the unit structure of the Peltier element 330 includes gold-plated electrodes 331, 332, and 335, a p-type semiconductor 333, and an n-type semiconductor 334. This unit structure is called a π-type thermoelectric conversion element.

The electrode 335 is formed on the ceramic substrate 340 on the lower side (heat absorption side). The electrodes 332 and 335 are formed on the ceramic substrate 320 on the upper side (heat dissipation side). The p-type semiconductor 333 and the n-type semiconductor 334 are connected to the electrode 335 by soldering. In addition, the p-type semiconductor 333 and an adjacent n-type semiconductor (not represented in the drawing) are connected to the electrode 331. The n-type semiconductor 334 and an adjacent p-type semiconductor (not represented in the drawing) are connected to the electrode 332.

In addition, as illustrated in a of the drawing, on the ceramic substrate 320, a plurality of electrodes 335, a plurality of p-type semiconductors 333, and a plurality of n-type semiconductors 334 are arrayed along the outer periphery of the opening 341. These semiconductors and electrodes form a plurality of units of π-type thermoelectric conversion elements and are connected in series. In addition, only the n-type semiconductors 334 are provided in the two electrodes 335 on the upper left, and these electrodes 335 are commonly connected to the terminal 342 in c of the drawing. In addition, only the p-type semiconductors 333 are provided in the two electrodes 335 on the lower right of a of the drawing, and these electrodes 335 are commonly connected to the terminal 343 in c of the drawing. With this configuration, when the control unit 110 drives the Peltier module 300, an electric current flows to the terminal 343 from the terminal 342 through the plurality of π-type thermoelectric exchange elements in the Peltier elements 330.

### Configuration Example of Interposer Substrate

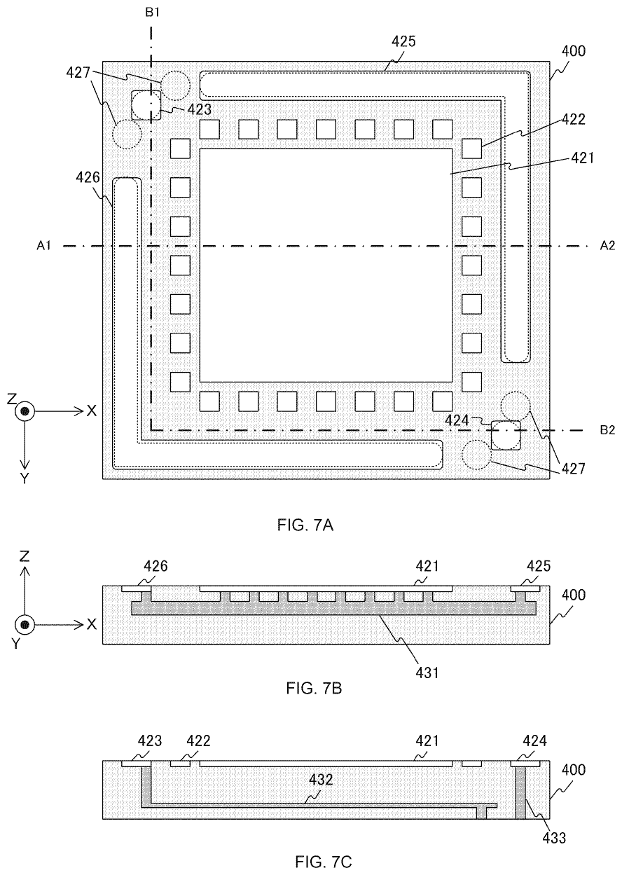

FIG. 7 depicts an example of a top view and a cross-sectional view of the interposer substrate 400 according to the first embodiment of the present technology. In the drawing, the peripheral components 412 and the connector 413 are omitted. In the drawing, a depicts an example of a top view of the interposer substrate 400. In the drawing, b depicts an example of a cross-sectional view when taken along line segment A1-A2 in a of the drawing. In the drawing, c depicts an example of a cross-sectional view when taken along line segment B1-B2 in a of the drawing.

As illustrated in a of the drawing, a rectangular attachment region 421 is disposed in a center portion of the upper surface of the interposer substrate 400. The attachment region 421 is a region for arranging the sensor chip 220 and is gold-plated.

In addition, a plurality of bumps 422 is arrayed along an outer periphery of the attachment region 421. One end of a wire is connected to the bump 422 at the time of wire bonding.

In addition, among four corners of the interposer substrate 400, a mounting land 423 is formed on the upper left, and a mounting land 424 is formed on the lower right. These mounting lands 423 and 424 are gold-plated and connected to the terminals 342 and 343 of the ceramic substrate 340 in FIG. 6.

In addition, L-shaped application regions 425 and 426 are formed along the outer periphery of the interposer substrate 400. These application regions 425 and 426 are regions for applying a conductive adhesive and are gold-plated. Application regions 427 for applying a non-conductive adhesive are provided between the mounting lands 423 and 424 and the application regions 425 and 426. The application regions 427 are not gold-plated. In addition, the adhesives are applied to the regions indicated by the dotted lines in a of the drawing.

Note that the application regions 425 and 426 are examples of a first application region described in the claims, and the application region 427 is an example of a second application region described in the claims.

As illustrated in b of the drawing, the application regions 425 and 426 and the attachment region 421 are commonly connected to each other by a copper foil 431 inside the interposer substrate 400. As a result, heat produced in the sensor chip 220 arranged in the attachment region 421 is conducted to the application regions 425 and 426 and is released to the Peltier module 300 (not represented in the drawing) on the upper surface.

In addition, as illustrated in c of the drawing, the mounting lands 423 and 424 are connected to one ends of signal lines 432 and 433, and the other ends of these signal lines are connected to the connector 413 (not represented in the drawing). An electric current is supplied to the Peltier module 300 from the control unit 110 via the signal lines 432 and 433.

### Method for Manufacturing Peltier Module

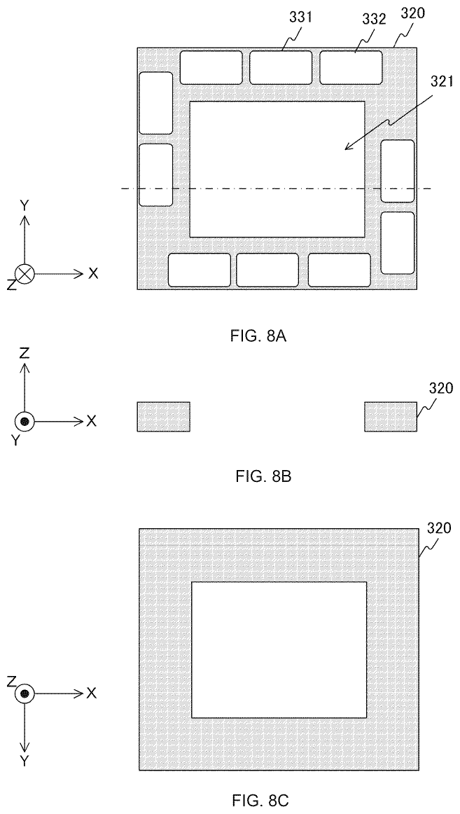

Next, a method for manufacturing the Peltier module 300 will be described with reference to FIGS. 8 to 16.

As illustrated in a of FIG. 8, electrodes such as the electrodes 331 and 332 are formed along the outer periphery of an opening 321 on the upper surface of the ceramic substrate 320 on the upper side (heat dissipation side). In the drawing, b is a cross-sectional view of the ceramic substrate 320 when taken along the dashed-dotted line in a of the drawing. In the drawing, c is a bottom view of the ceramic substrate 320. At this point in time, the surface facing the ceramic substrate 340 is on the upper side, and the upper and lower sides are reversed as compared with b of FIG. 5.

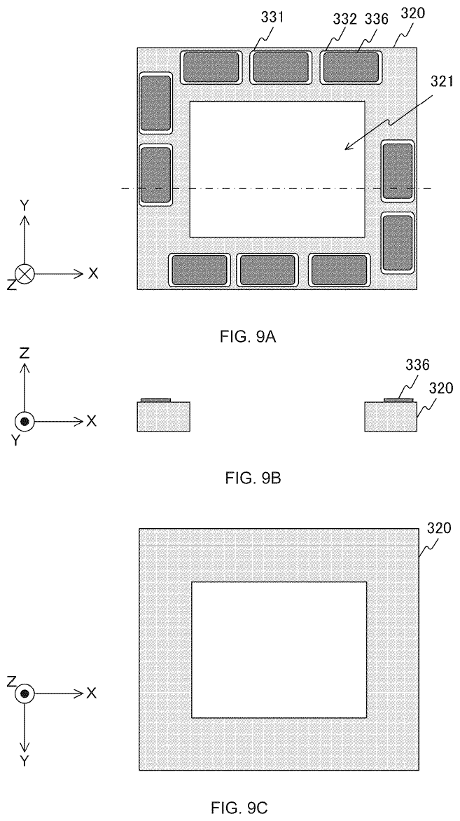

Then, as illustrated in a of FIG. 9, a solder 336 is applied to each of the electrodes on the upper surface of the ceramic substrate 320. In the drawing, b is a cross-sectional view of the ceramic substrate 320 when taken along the dashed-dotted line in a of the drawing. In the drawing, c is a bottom view of the ceramic substrate 320. At this point in time, the surface facing the ceramic substrate 340 is on the upper side, and the upper and lower sides are reversed as compared with b of FIG. 5.

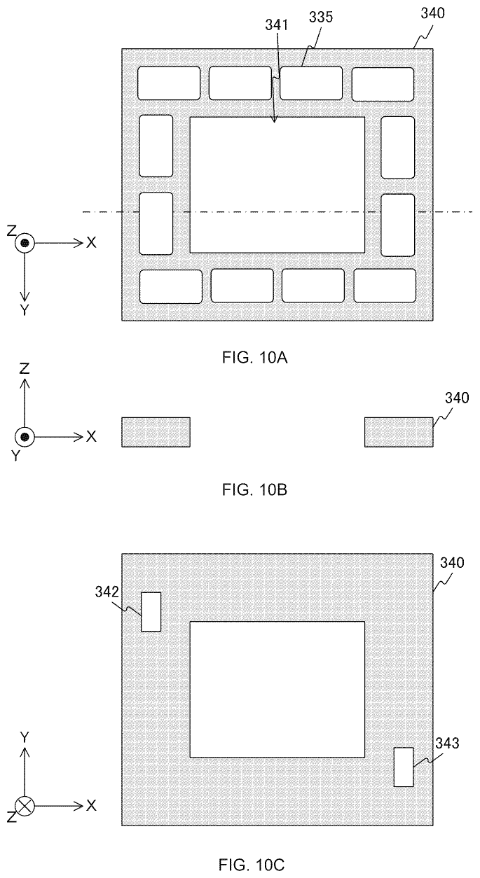

In addition, as illustrated in a of FIG. 10, a plurality of electrodes 335 is formed along the outer periphery of the opening 341 on the upper surface of the ceramic substrate 340 on the lower side (heat absorption side). In the drawing, b is a cross-sectional view of the ceramic substrate 340 when taken along the dashed-dotted line in a of the drawing. In the drawing, c is a bottom view of the ceramic substrate 340.

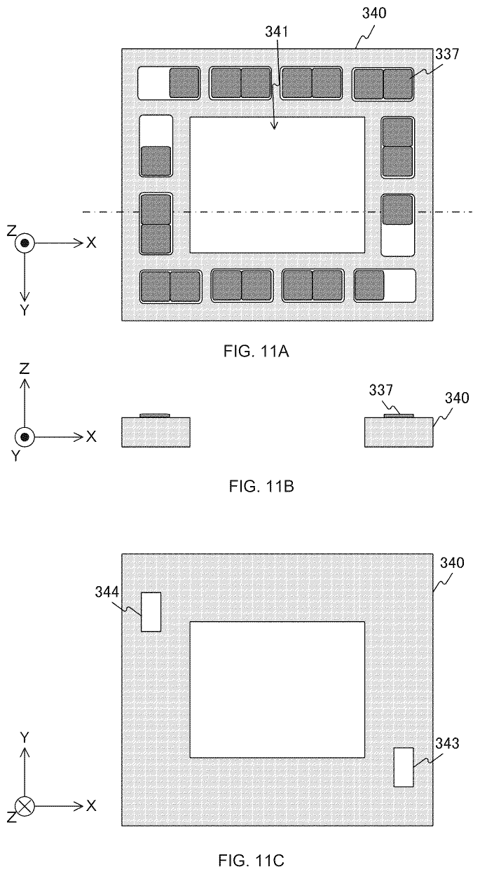

Then, as illustrated in a of FIG. 11, a solder 337 is applied to each of the electrodes on the upper surface of the ceramic substrate 340. In the drawing, b is a cross-sectional view of the ceramic substrate 340 when taken along the dashed-dotted line in a of the drawing. In the drawing, c is a bottom view of the ceramic substrate 340.

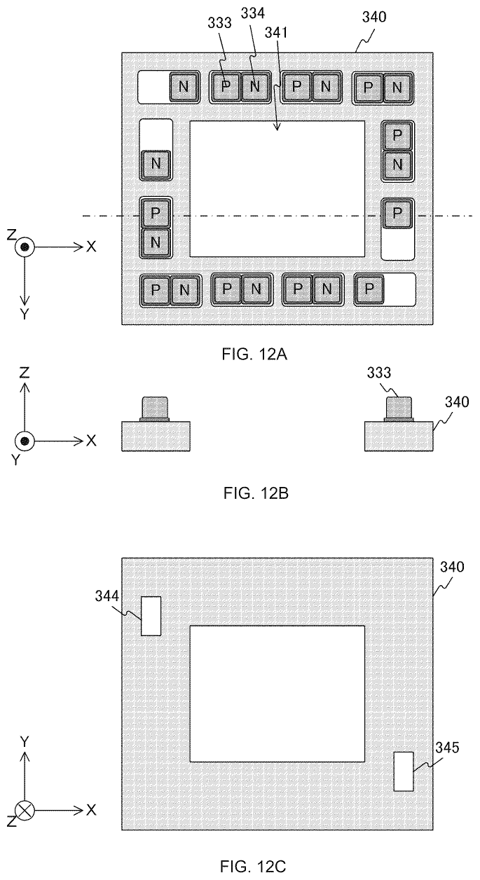

Next, as illustrated in a of FIG. 12, the p-type semiconductor 333 and the n-type semiconductor 334 are soldered to each of the electrodes on the upper surface of the ceramic substrate 340. These p-type semiconductor 333 and n-type semiconductor 334 are alternately arrayed along the outer periphery of the opening 341. In the drawing, b is a cross-sectional view of the ceramic substrate 340 when taken along the dashed-dotted line in a of the drawing. In the drawing, c is a bottom view of the ceramic substrate 340.

The steps from FIG. 8 to FIG. 9 and the steps from FIG. 10 to FIG. 12 may be performed in parallel or in order.

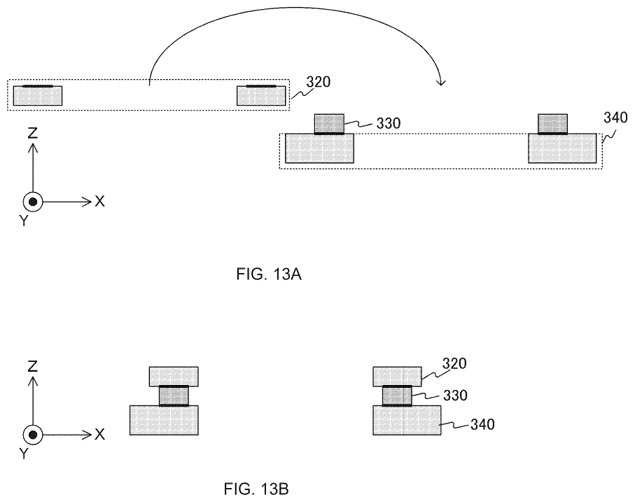

Then, as illustrated in a of FIG. 13, the ceramic substrate 320 is turned upside down and soldered to the Peltier elements 330 on the upper surface of the ceramic substrate 340. In the drawing, b represents a completed state of soldering.

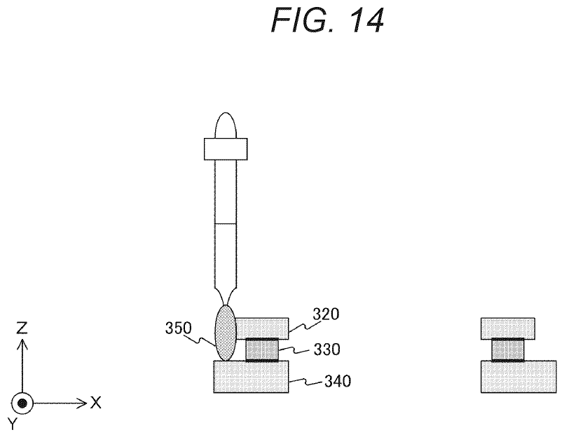

Subsequently, as illustrated in FIG. 14, the sealing resin 350 is applied to a peripheral edge of the ceramic substrate 340.

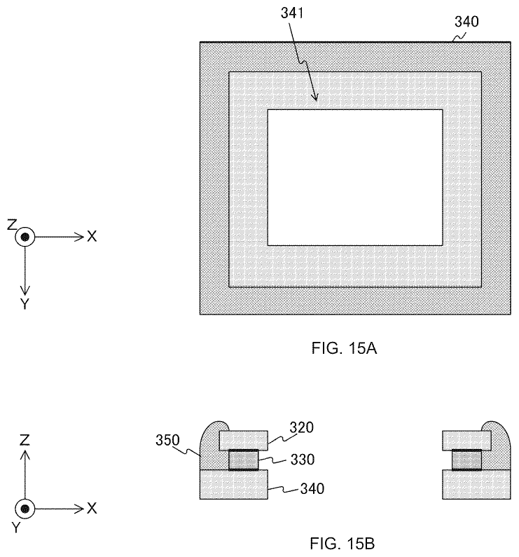

In FIG. 15, a represents a top view in a completed state of the application of the sealing resin 350, and b of the drawing represents a cross-sectional view in the completed state. As illustrated in b of the drawing, the sealing resin 350 is applied so as to be higher than the ceramic substrate 320.

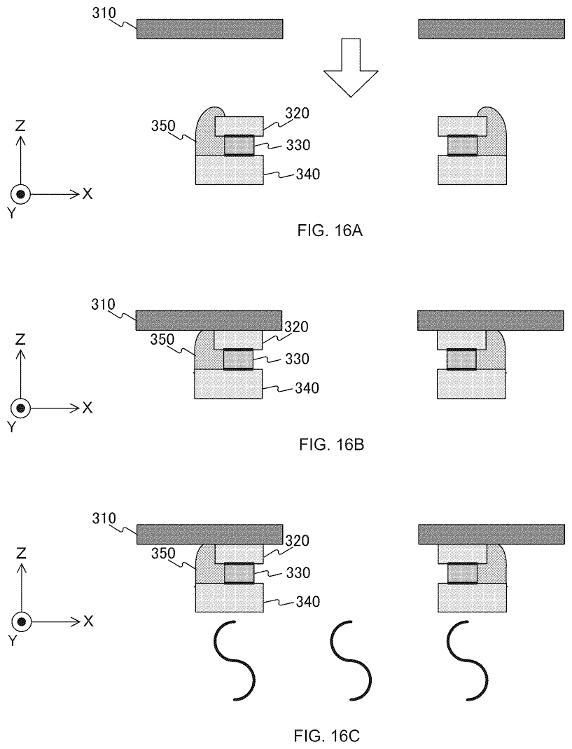

Then, as illustrated in a of FIG. 16, the metal plate 310 is accurately affixed in close contact. In the drawing, b represents an affixed state. Then, as illustrated in c of the drawing, the sealing resin 350 is cured by heating.

### Method for Manufacturing Semiconductor Package

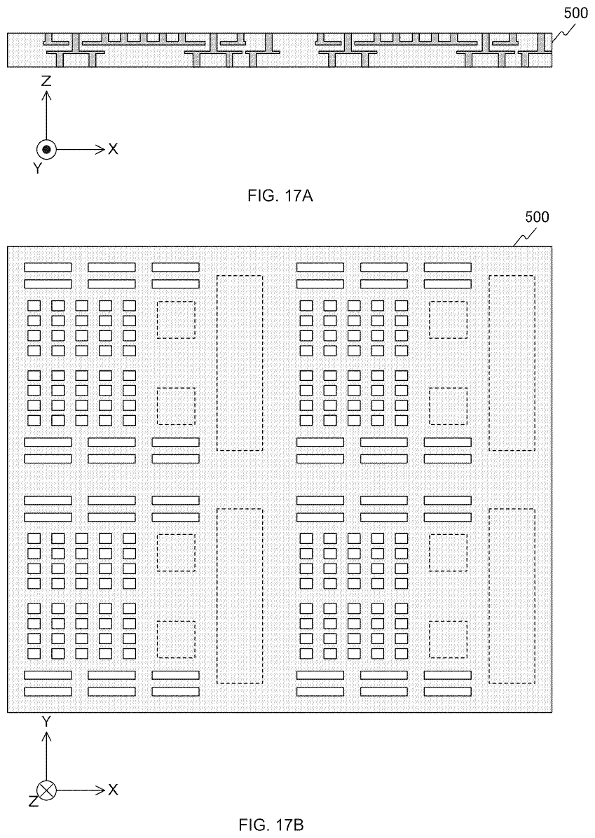

Next, steps for manufacturing the semiconductor package 200 using the Peltier module 300 obtained by the steps in FIGS. 8 to 16 will be described with reference to FIGS. 17 to 26.

As illustrated in FIG. 17, an organic substrate 500 including a plurality of interposer substrates is created. In the drawing, a is a cross-sectional view of the organic substrate 500, and b of the drawing is a bottom view of the organic substrate 500.

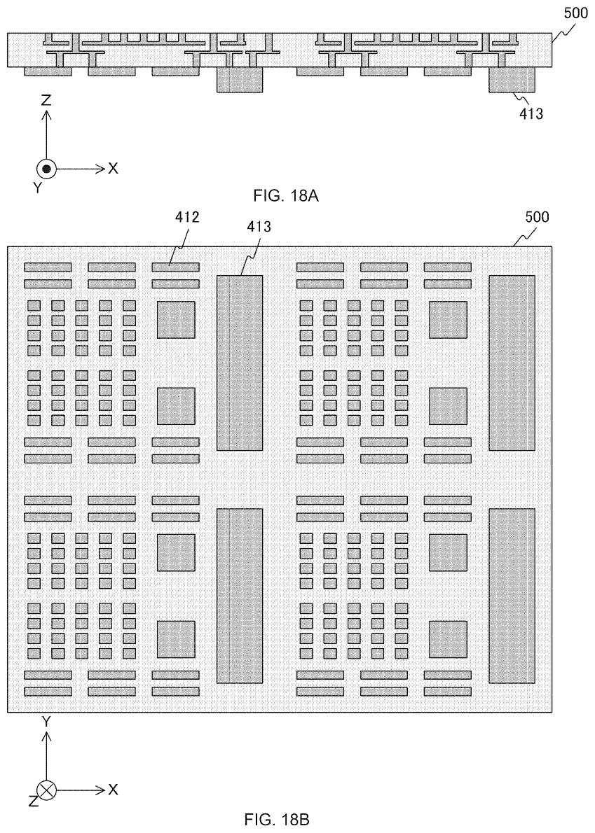

Next, as illustrated in FIG. 18, the peripheral components 412 and the connectors 413 are mounted on the lower surface of the organic substrate 500 by soldering. In the drawing, a is a cross-sectional view of the organic substrate 500, and b of the drawing is a bottom view of the organic substrate 500.

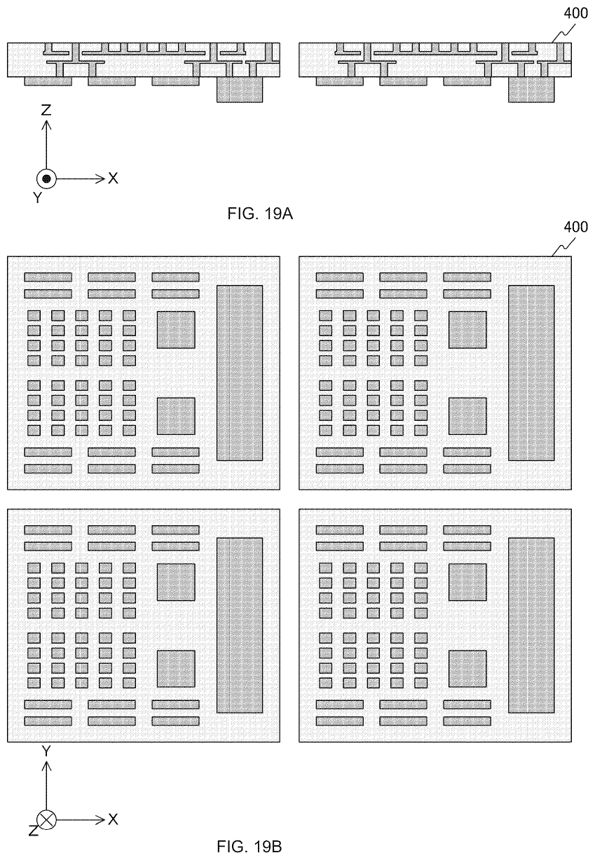

Next, as illustrated in FIG. 19, a plurality of interposer substrates 400 is obtained by dicing. In the drawing, a is a cross-sectional view of the interposer substrates 400, and b of the drawing is a bottom view of the interposer substrates 400.

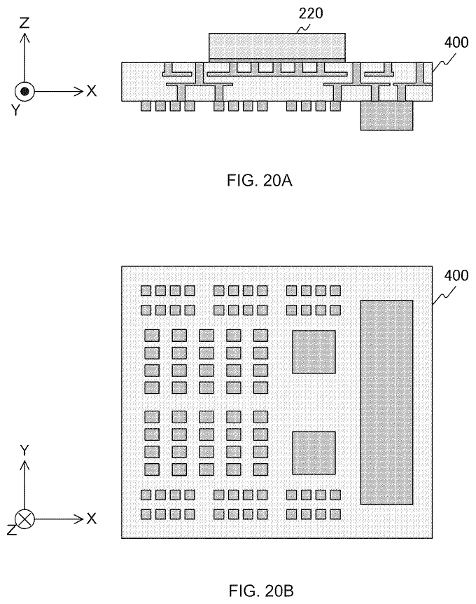

Next, as illustrated in a of FIG. 20, the sensor chip 220 is die-bonded to the upper surface of the interposer substrate 400. In the drawing, b is a bottom view of the interposer substrate 400.

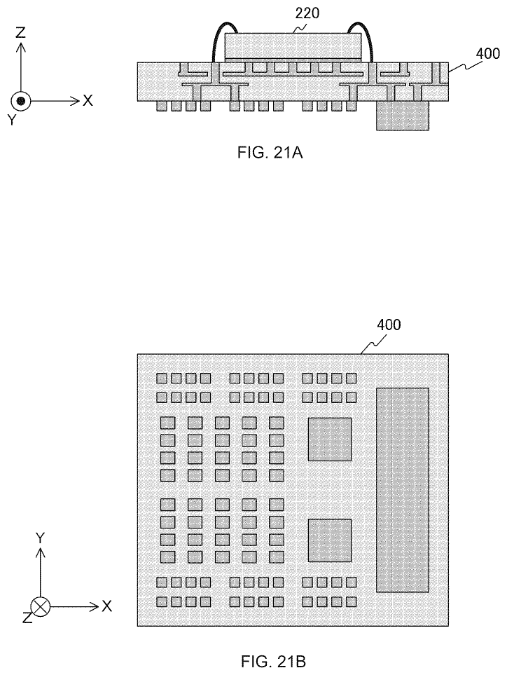

Next, as illustrated in a of FIG. 21, the sensor chip 220 is electrically connected to the interposer substrate 400 by a wire. In the drawing, b is a bottom view of the interposer substrate 400.

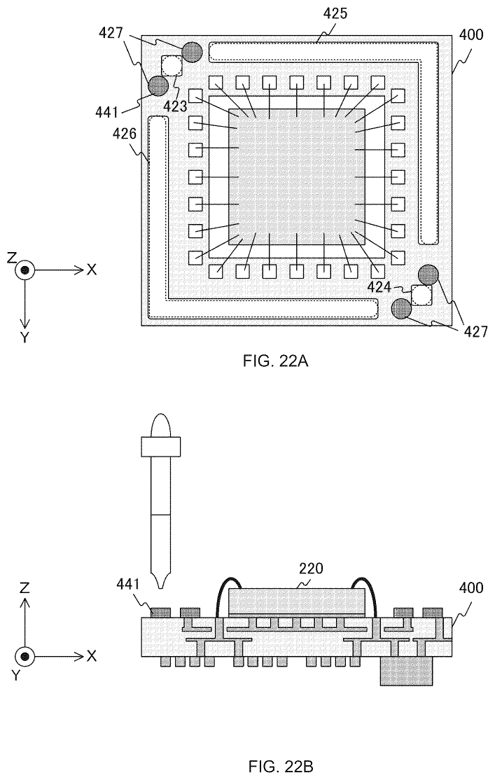

Next, as illustrated in a and b of FIG. 22, a non-conductive adhesive 441 is applied to the application regions 427 between the mounting lands 423 and 424 and the gold-plated application regions 425 and 426.

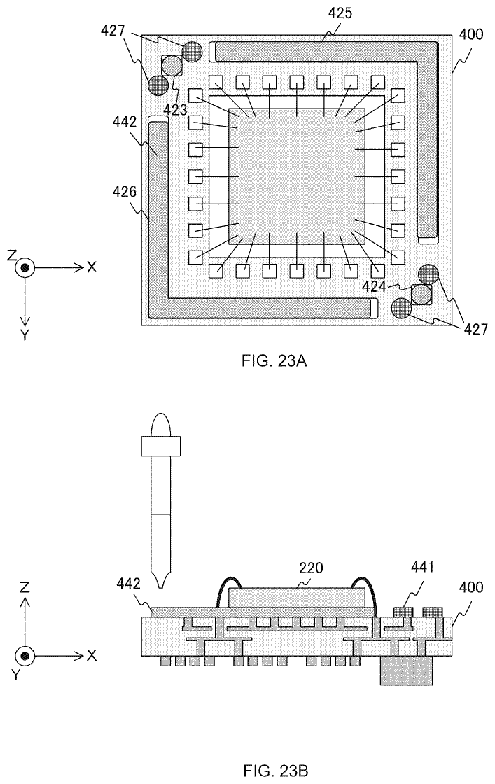

In addition, as illustrated in a and b of FIG. 23, a conductive adhesive 442 is applied to each of the mounting lands 423 and 424 and the gold-plated application regions 425 and 426.

The volume resistivity of the conductive adhesive 442 is, for example, 8×10⁻⁴ ohm centimeters (Ω·cm). In addition, the diameter of the application region 427 is larger than the width and diameter of each of the mounting lands 423 and 424 and the application regions 425 and 426. Therefore, the mounting lands 423 and 424 are insulated from the application regions 425 and 426 by the non-conductive adhesive 441 in the application regions 427.

In addition, as the non-conductive adhesive 441 and the conductive adhesive 442, for example, a silicone or epoxy thermosetting resin having a viscosity of 30 pascal seconds (Pa·s) or more and high thixotropy and having little outgassing is used.

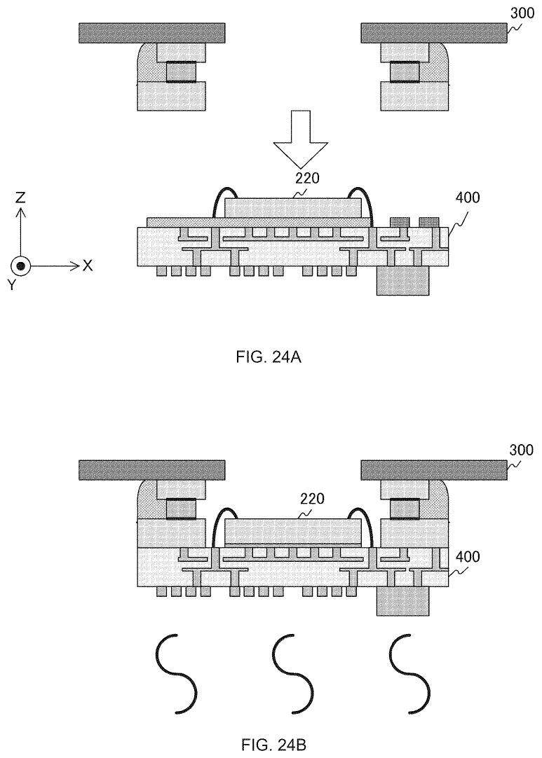

Next, as illustrated in a of FIG. 24, the Peltier module 300 is accurately placed on the interposer substrate 400 and pressurized. Then, as illustrated in b of the drawing, heat is applied in a state in which a gap of the adhesives between the Peltier module 300 and the interposer substrate 400 is eliminated, and the adhesives are cured.

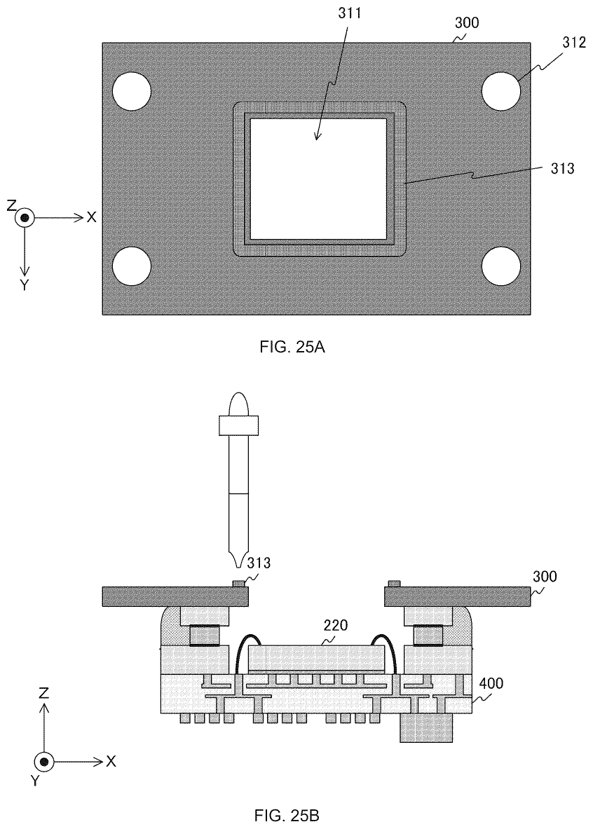

Subsequently, as illustrated in a of FIG. 25, an adhesive 313 is applied on a periphery of the opening 311 on the upper surface of the Peltier module 300. As the adhesive 313, for example, an ultraviolet curable resin is used. In the drawing, b is a cross-sectional view of the semiconductor package 200 before arranging the glass 210.

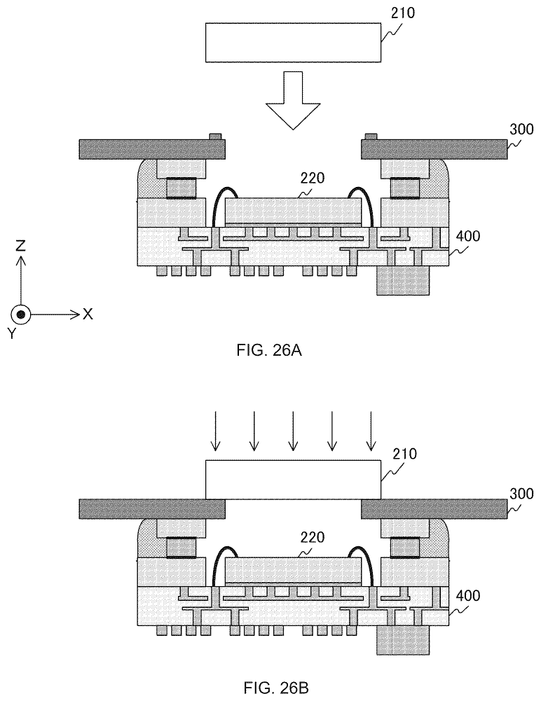

Then, the glass 210 is arranged as illustrated in a of FIG. 26, and the adhesive 313 is cured by being irradiated with ultraviolet rays as illustrated in b of the drawing. As a result, the cavity is sealed off. Note that a thermosetting resin can also be used as the adhesive 313 and cured by heating.

### Control Example of Semiconductor Package

The flowchart represents an example of a method for controlling the semiconductor package according to the first embodiment of the present technology. This control is started by the control unit 110, for example, when a predetermined application for capturing image data is executed.

The control unit 110 obtains the temperature of the sensor chip 220 at a predetermined timing (for example, periodically) (step S901) and determines whether or not the obtained temperature is higher than a predetermined upper limit value (step S902). In a case where the temperature is equal to or lower than the upper limit value (step S902: No), the control unit 110 repeats step S901.

On the other hand, in a case where the temperature is higher than the upper limit value (step S902: Yes), the control unit 110 starts supply of an electric current to the Peltier module 300 (step S903). During operation of the Peltier module 300, the control unit 110 obtains the temperature of the sensor chip 220 at a predetermined timing (for example, periodically) (step S904) and determines whether or not the temperature is higher than the predetermined upper limit value (step S905).

In a case where the temperature is equal to or lower than the upper limit value (step S905: No), the control unit 110 stops supply of the electric current to the Peltier module 300 (step S909) and repeats step S901 and the subsequent steps.

On the other hand, in a case where the temperature is higher than the upper limit value (step S905: Yes), the control unit 110 obtains the battery remaining amount (step S906) and determines whether or not the obtained battery remaining amount exceeds a predetermined lower limit value (step S907). In a case where the battery remaining amount exceeds the lower limit value (step S907: Yes), the control unit 110 repeats step S904 and the subsequent steps.

On the other hand, in a case where the battery remaining amount is equal to or lower than the lower limit value (step S907: No), the control unit 110 instructs the sensor chip 220 to stop the imaging operation (step S908) and ends the control. Note that, in step S908, the control unit 110 can also externally output a predetermined alarm relating to the temperature rise.

As illustrated in the drawing, electric power can be saved by controlling the Peltier module 300 to perform cooling only in a case where cooling is necessary.

As described above, according to the first embodiment of the present technology, since the Peltier module 300 is connected to the upper surface of the interposer substrate 400 together with the sensor chip 220, components can be easily mounted on the lower surface of the interposer substrate 400. As a result, the substrate area can be made narrower than that of the comparative example, and the semiconductor package 200 can be miniaturized.

### 2. Second Embodiment

In the first embodiment described above, a ceramic substrate is used as the substrate of the Peltier module 300, but a substrate other than the ceramic substrate can also be used. A Peltier module 300 according to a second embodiment is different from that in the first embodiment in that a sapphire substrate is used.

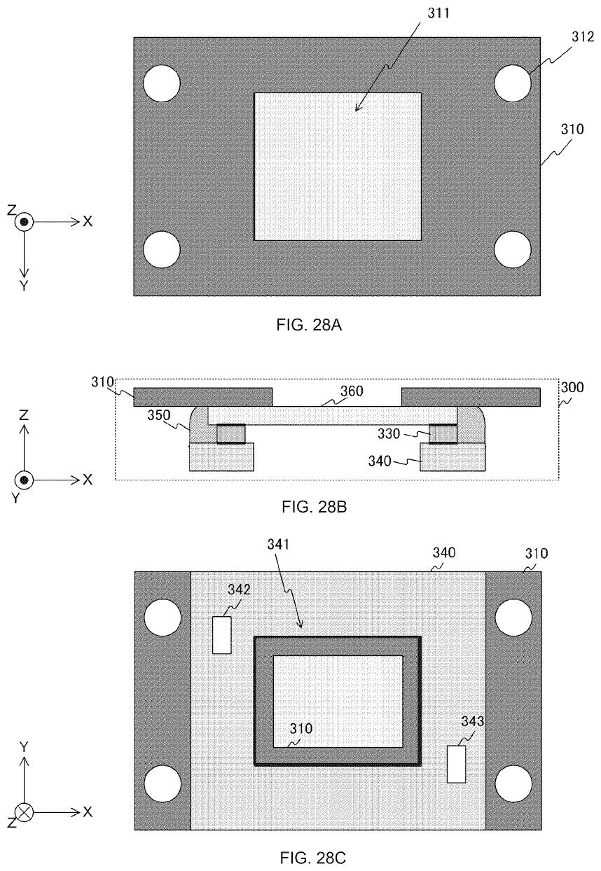

FIG. 28 depicts an example of a top view, a cross-sectional view, and a bottom view of the Peltier module 300 according to the second embodiment of the present technology. In the drawing, a is a top view of the Peltier module 300, and b of the drawing is a cross-sectional view of the Peltier module 300. In the drawing, c is a bottom view of the Peltier module 300.

The Peltier module 300 according to the second embodiment is different from that in the first embodiment in that a transparent sapphire substrate 360 having no opening is disposed on the upper side (heat dissipation side) instead of the ceramic substrate 320. Note that the sapphire substrate 360 is an example of a transparent substrate described in the claims.

As illustrated in the drawing, by using the sapphire substrate 360, the glass 210 is no longer necessary, and the height of a semiconductor package 200 can be lowered.

In this manner, according to the second embodiment of the present technology, since the sapphire substrate 360 is disposed in the Peltier module 300, the glass 210 no longer needs to be provided.

### 3. Third Embodiment

In the first embodiment described above, a ceramic substrate is used as the substrate of the Peltier module 300, but a substrate other than the ceramic substrate can also be used. A Peltier module 300 according to a third embodiment is different from that in the first embodiment in that a flexible substrate is used.

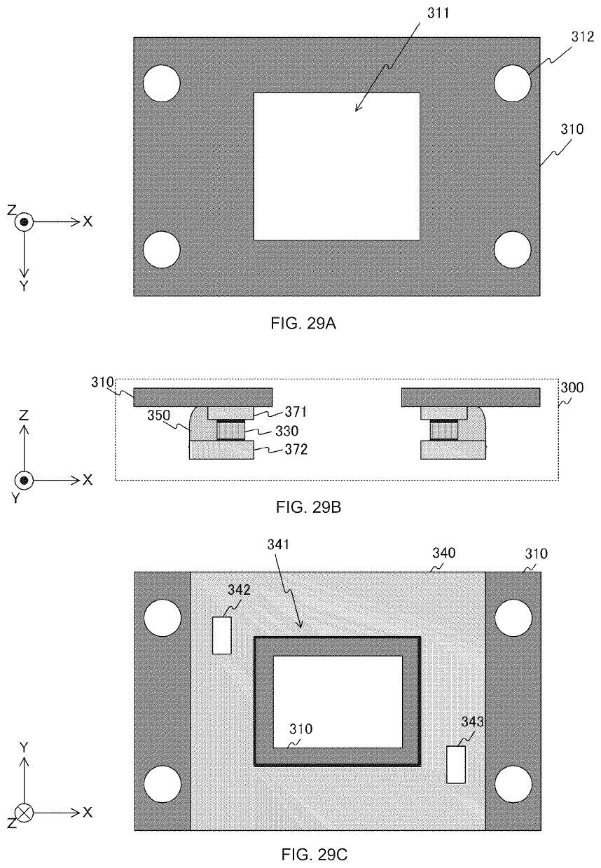

FIG. 29 depicts an example of a top view, a cross-sectional view, and a bottom view of the Peltier module 300 according to the third embodiment of the present technology. In the drawing, a is a top view of the Peltier module 300, and b of the drawing is a cross-sectional view of the Peltier module 300. In the drawing, c is a bottom view of the Peltier module 300.

The Peltier module 300 according to the third embodiment is different from that in the first embodiment in that flexible substrates 371 and 372 are disposed instead of the ceramic substrates 320 and 340. The flexible substrates 371 and 372 have openings similarly to the ceramic substrates 320 and 340.

As illustrated in the drawing, by using the flexible substrates 371 and 372, the weight of a semiconductor package 200 can be made still lighter by making the substrates thinner than those in the first embodiment.

Note that the second embodiment can be applied to the third embodiment. In this case, the flexible substrate 371 on the upper side is replaced with the sapphire substrate 360.

As described above, according to the third embodiment of the present technology, since the flexible substrates 371 and 372 are disposed in the Peltier module 300, the weight of the semiconductor package 200 can be made still lighter.

### 4. Example of Application to Mobile Object

The technology according to the present disclosure (the present technology) can be applied to various products. For example, the technology according to the present disclosure may be implemented as a device arranged on any type of mobile object such as an automobile, an electric vehicle, a hybrid electric vehicle, a motorcycle, a bicycle, a personal mobility, an airplane, a drone, a ship, or a robot.

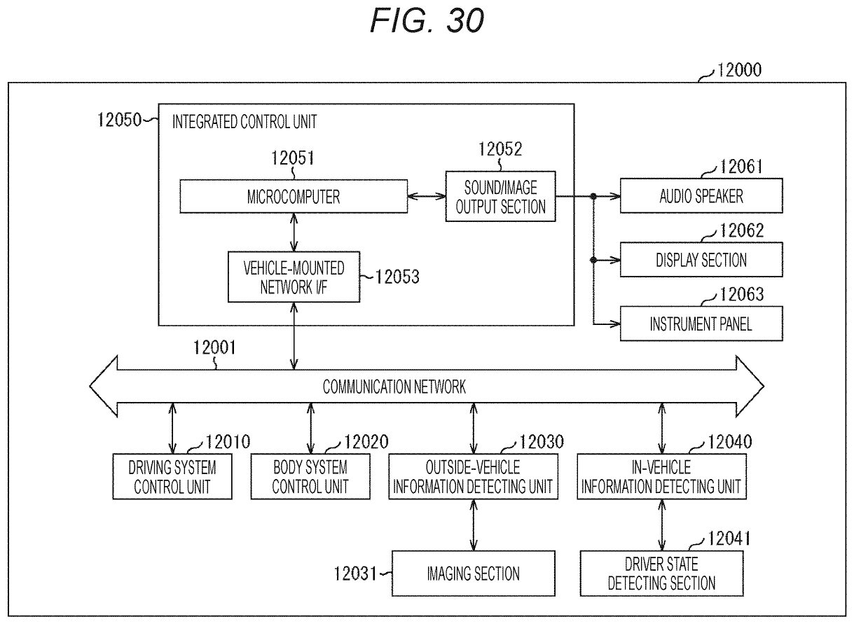

FIG. 30 is a block diagram representing a schematic configuration example of a vehicle control system as an example of a mobile object control system to which the technology according to the present disclosure can be applied.

The vehicle control system 12000 includes a plurality of electronic control units connected to each other via a communication network 12001. In the example illustrated in FIG. 30, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are represented in the drawing as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of information about the outside of the vehicle, the information being obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example in FIG. 30, an audio speaker 12061, a display section 12062, and an instrument panel 12063 are illustrated as the output device. The display section 12062 may, for example, include at least one of an on-board display and a head-up display.

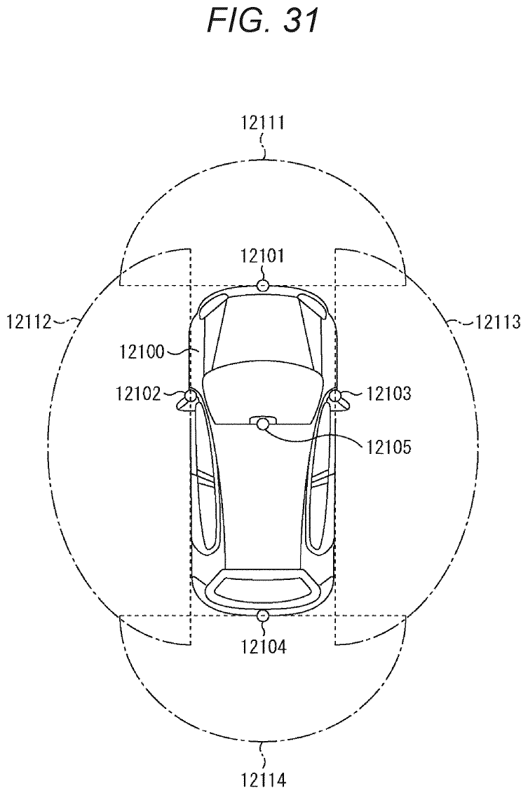

FIG. 31 is a diagram representing an example of the installation positions of the imaging section 12031.

In FIG. 31, the imaging section 12031 includes imaging sections 12101, 12102, 12103, 12104, and 12105.

The imaging sections 12101, 12102, 12103, 12104, and 12105 are provided at, for example, positions on a front nose, sideview mirrors, a rear bumper, and a back door of a vehicle 12100, an upper portion of a windshield within the interior of the vehicle, and the like. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that FIG. 31 represents an example of the imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied, for example, to the imaging section 12031 among the constituents described above. Specifically, the imaging device 100 in FIG. 1 can be applied to the imaging section 12031. By applying the technology according to the present disclosure to the imaging section 12031, the imaging device 100 can be miniaturized and an installation space can be made to have a margin.

Note that the above embodiments represent examples for embodying the present technology, and matters in the embodiments and matters specifying the invention in the claims each have a correspondence relationship. Similarly, the matters specifying the invention in the claims and matters with the same names in the embodiments of the present technology each have a correspondence relationship. However, the present technology is not limited to the embodiments and may be embodied by variously modifying the embodiments without departing from the scope thereof.

Note that advantageous effects described in the present description are merely illustrative and not restrictive, and other advantageous effects may also be provided.

(1) A semiconductor package including:
a mounting substrate;
a semiconductor chip arranged in an attachment region in a substrate plane of the mounting substrate; and
a Peltier module connected to a periphery of the attachment region in the substrate plane.

(2) The semiconductor package according to (1) above, in which
the Peltier module includes:
a heat dissipation-side substrate;
a heat absorption side substrate connected to the mounting substrate; and
a Peltier element disposed between the heat dissipation-side substrate and the heat absorption-side substrate.

(3) The semiconductor package according to (2) above, in which
both the heat dissipation-side substrate and the heat absorption-side substrate include flexible substrates each having an opening.

(4) The semiconductor package according to (2) above, in which
the heat absorption-side substrate includes a ceramic substrate having an opening.

(5) The semiconductor package according to (4) above, in which
the heat dissipation-side substrate includes a ceramic substrate having an opening.

(6) The semiconductor package according to (4) above, in which
the heat dissipation-side substrate includes a transparent substrate.

(7) The semiconductor package according to any one of (1) to (6) above, in which
the Peltier module includes:
a metal plate having an opening;
a heat dissipation-side substrate connected to the metal plate;
A Heat Absorption-side Substrate Connected to the Mounting substrate; and
a Peltier element disposed between the heat dissipation-side substrate and the heat absorption-side substrate.

(8) The semiconductor package according to (7) above, in which
the metal plate is fixed to an attachment portion, and
a linear expansion coefficient and a thermal conductivity of the metal plate are larger than the linear expansion coefficient and the thermal conductivity of the heat dissipation-side substrate and smaller than the linear expansion coefficient and the thermal conductivity of the attachment portion.

(9) The semiconductor package according to (7) or (8) above, in which
the Peltier module further includes a sealing resin that seals respective side surfaces of the heat dissipation-side substrate and the Peltier element.

(10) The semiconductor package according to any one of (1) to (9) above, in which
the semiconductor chip photoelectrically converts incident light to generate image data.

(11) The semiconductor package according to any one of (1) to (10) above, further including
a glass that seals off a space formed by the Peltier module and the mounting substrate.

(12) The semiconductor package according to any one of (1) to (12) above, in which
a first application region along an outer periphery of the mounting substrate, a mounting land to which the Peltier module is connected, and a second application region between the application region and the mounting land are disposed on the substrate plane,
the mounting land and the first application region are bonded to the Peltier module with a conductive adhesive, and
the second application region is bonded to the Peltier module with a non-conductive adhesive.

(13) An electronic device including:
a mounting substrate;
a semiconductor chip arranged in an attachment region in a substrate plane of the mounting substrate;
a Peltier module connected to a periphery of the attachment region in the substrate plane; and
a control unit that supplies an electric current to the Peltier module.

(14) The electronic device according to (13) above, in which
the control unit obtains a temperature of the semiconductor chip, and supplies the electric current in a case where the temperature is higher than a predetermined upper limit value.

(15) A method for manufacturing a semiconductor package, the method including:
a chip arrangement procedure of arranging a semiconductor chip in an attachment region in a substrate plane of a mounting substrate; and
a connection procedure of connecting a Peltier module to a periphery of the attachment region in the substrate plane.

### REFERENCE SIGNS LIST

100 Imaging device
110 Control unit
120 Battery remaining amount measurement unit
130 Battery
140 Image processing unit
150 Storage unit
161 Attachment portion
162 Heat conductive sheet
163 Screw
200 Semiconductor package
210 Glass
220 Sensor chip
230 Flexible cable
300 Peltier module
310 Metal plate
311, 321, 341 Opening
312 Screw hole
313 Adhesive
320, 340 Ceramic substrate
330 Peltier element
331, 332, 335 Electrode
333 p-type semiconductor
334 n-type semiconductor
336, 337 Solder
342, 343 Terminal
350 Sealing resin
360 Sapphire substrate
371, 372 Flexible substrate
400 Interposer substrate
411 Temperature sensor
412 Peripheral component
413 Connector
421 Attachment region
422 Bump
423, 424 Mounting land
425, 426, 427 Application region
431 Copper foil
432, 433 Signal line
441 Non-conductive adhesive
442 Conductive adhesive
500 Organic substrate
12031 Imaging section

1. A semiconductor package comprising:
a mounting substrate;
a semiconductor chip arranged in an attachment region in a substrate plane of the mounting substrate; and
a Peltier module connected to a periphery of the attachment region in the substrate plane.

2. The semiconductor package according to claim 1, wherein
the Peltier module includes:
a heat dissipation-side substrate;
a heat absorption-side substrate connected to the mounting substrate; and
a Peltier element disposed between the heat dissipation-side substrate and the heat absorption-side substrate.

3. The semiconductor package according to claim 2, wherein
both the heat dissipation-side substrate and the heat absorption-side substrate include flexible substrates each having an opening.

4. The semiconductor package according to claim 2, wherein
the heat absorption-side substrate includes a ceramic substrate having an opening.

5. The semiconductor package according to claim 4, wherein
the heat dissipation-side substrate includes a ceramic substrate having an opening.

6. The semiconductor package according to claim 4, wherein
the heat dissipation-side substrate includes a transparent substrate.

7. The semiconductor package according to claim 1, wherein
the Peltier module includes:
a metal plate having an opening;
a heat dissipation-side substrate connected to the metal plate;
a heat absorption-side substrate connected to the mounting substrate; and
a Peltier element disposed between the heat dissipation-side substrate and the heat absorption-side substrate.

8. The semiconductor package according to claim 7, wherein
the metal plate is fixed to an attachment portion, and
a linear expansion coefficient and a thermal conductivity of the metal plate are larger than the linear expansion coefficient and the thermal conductivity of the heat dissipation-side substrate and smaller than the linear expansion coefficient and the thermal conductivity of the attachment portion.

9. The semiconductor package according to claim 7, wherein
the Peltier module further includes a sealing resin that seals respective side surfaces of the heat dissipation-side substrate and the Peltier element.

10. The semiconductor package according to claim 1, wherein
the semiconductor chip photoelectrically converts incident light to generate image data.

11. The semiconductor package according to claim 1, further comprising
a glass that seals off a space formed by the Peltier module and the mounting substrate.

12. The semiconductor package according to claim 1, wherein
a first application region along an outer periphery of the mounting substrate, a mounting land to which the Peltier module is connected, and a second application region between the application region and the mounting land are disposed on the substrate plane,
the mounting land and the first application region are bonded to the Peltier module with a conductive adhesive, and
the second application region is bonded to the Peltier module with a non-conductive adhesive.

13. An electronic device comprising:
a mounting substrate;
a semiconductor chip arranged in an attachment region in a substrate plane of the mounting substrate;
a Peltier module connected to a periphery of the attachment region in the substrate plane; and
a control unit that supplies an electric current to the Peltier module.

14. The electronic device according to claim 13, wherein
the control unit obtains a temperature of the semiconductor chip, and supplies the electric current in a case where the temperature is higher than a predetermined upper limit value.

15. A method for manufacturing a semiconductor package, the method comprising:
a chip arrangement procedure of arranging a semiconductor chip in an attachment region in a substrate plane of a mounting substrate; and
a connection procedure of connecting a Peltier module to a periphery of the attachment region in the substrate plane.
